(19) United States
(12) Patent Application Publication
(10) Pub. No.: US 2003/0025485 A1
(43) Pub. Date: Feb. 6, 2003

(54) Two path wide-band probe using pole-zero cancellation

(76) Inventor: Michael T. McTigue, Colorado Springs, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 09/920,097

(22) Filed: Aug. 1, 2001

(51) Int. Cl. G01R 31/02

(52) U.S. Cl. 324/72.5

(57) ABSTRACT

A probe apparatus with a probe network consisting of two electrical paths. One path is a dc path and the other path is an ac path. The separation of the dc and ac currents allows wide-band probing of circuits with a low mass probe tip that has acceptable input impedance.

### BACKGROUND

This invention is concerned generally with probes, and more specifically with probes for detecting and replicating high speed electronic signals with minimum disturbance of signal and maximum fidelity of replication, commonly used with devices for analyzing the detected signals, including, for example, oscilloscopes.

The usefulness of a probe depends upon the range of frequencies for which the response is true to the detected signal, the accuracy of replication, and the extent to which the probe detects the signal without detrimentally affecting the operation of the system or circuit being probed. If the input resistance of the combined probe and end-use device is the same order of magnitude as that of the circuit or system being probed, it may cause errors in the replication of the signal or a change in the operation of the circuit or system resulting in erroneous output or circuit malfunction. High probe tip capacitance will also cause circuit loading problems at higher frequencies. Designing the probe to have hi input impedance relative to the impedance of the circuit being probed at the point of probing has been the common protection against these errors. This high impedance caused very little current to flow through the probe, allowing the circuit to operate relatively undisturbed.

The frequency response of a probe is partially dependent upon the network formed by the source impedance of the point being probed and the input impedance of the probe. The capacitive reactance varies as a function of frequency causing the impedance of the probe to vary with frequency. This has limited the effective bandwidth of prior art available probes, because the impedance of the probes falls at high frequencies. Minimizing the capacitance of the probe tip has been one solution for increasing the useful bandwidth of the probe. However, the probe tip capacitance has been proportional to the probe cable length, making tip capacitance difficult to erase. Compensating for the capacitance by using active electronics at the probe tip has been a second alternative which has been used for extending the effective bandwidth of the probe tip. This generally has caused the probe tip to be bulky and easily damaged.

Typical probes available in the prior art included high resistance probes which minimized resistive loading and had high input impedance at dc, but the impedance fell off rapidly with increasing frequency due to high input capacitance. High impedance cable was used with these probes to minimize capacitance, but this cable was very lossy at high frequencies, limiting bandwidth. These probes also required the measuring instrument to have a high impedance.

Prior art wide-band probes usually are of the active type where the active electronics are made as small as possible and placed as close to the probe tip as possible so connection parasitics are minimized. These probes were active field effect transistor probes which had active electronics at the probe tip to compensate for loading problems due to low input impedance. These probes had a higher input resistance than the resistive divider probes and a lower capacitance than the high impedance probes, but were limited in bandwidth by the available field effect transistors and were bulky and easily damaged. This approach has other disadvantages. One significant disadvantage is that the size and mass of the actual probe tip are still larger that optimum.

Wide bandwidth probes with pole/zero cancellation have been utilized in probe tips. One such probe is described in U.S. Pat. No. 4,743,839 to Kenneth Rush, included herein by reference. The Rush patent describes a probe apparatus for use with analyzing devices, primarily oscilloscopes, which uses pole-zero cancellation to provide a probe with low capacitance and wide bandwidth. Pole-zero cancellation enables the probe to have constant gain at most frequencies. In one embodiment of the Rush patent, a coaxial cable between the probe tip and the replication amplifier is terminated in its characteristic impedance to provide constant gain at all frequencies regardless of cable length. However, though this solution allowed a low mass passive probe tip, it limited the input resistance to approximately 10 kΩ due to DC stability issues.

Also available were passive divider probes which had the lowest input capacitances available in a probe and therefore had a very broad bandwidth. However, the low input resistance could cause problems with resistive loading which could force the circuit under test into saturation, nonlinear operation, or to stop operating completely.

In other fields, a concept called pole-zero cancellation has been known. One application in which the concept was used was in a system for measuring heart rate disclosed in U.S. Pat. No. 4,260,951 of Lanny L. Lewyn. In that system, pole-zero cancellation was used to cancel the long differentiation time constant so as to remove undesired shaping of the heart pressure wave caused by the second order feedback loop. This allowed the waveform to be refined so that it could enable greater accuracy in measuring the heart rate.

### SUMMARY

The invention is generally to be used in probing devices of an electrical nature, with a preferred emboOdiment being used as a probe for an oscilloscope. The invention uses an application of the concept of pole-zero cancellation to improve the frequency response of the probe, and the concept of separating the ac and dc paths.

In a preferred embodiment of the invention, the probe network consists of two electrical paths. One path is a dc path and the other path is an ac path. The separation of the dc and ac currents allows wide-band probing of circuits with a low mass probe tip that has acceptable input impedance. Further, the preferred embodiment of the invention further allows the dc signal sensed by a probe tip to be optimized separately from the ac signal. This offers improved dc stability and a larger dc offset range over the prior art.

The preferred embodiment of the invention also provides pole-zero cancellation. The invention allows for two sets of poles and zeros which cancel each other out, resulting in an overall flat frequency response.

The overall result is a probe which can have a high input impedance enabling the probe to detect an electronic signal in a system under test without disturbing it and be responsive over a wider range of frequencies than most available prior art probes.

### DESCRIPTION OF THE DRAWINGS

FIG. 1 is a general block diagram of a probe according to the invention.

FIG. 2 is a schematic of a probe tip network according to the invention.

FIG. 3 is a schematic of an ac path network according to the invention.

FIG. 4 is a schematic of a dc path network according to the invention.

FIG. 5 is a schematic of the combination network in accordance with the invention.

FIG. 6 is a schematic of a probe network according to the invention.

FIGS. 7A-C are bode plots representing the frequency response of portions of a probe network according to the invention.

### DETAILED DESCRIPTION OF THE INVENTION

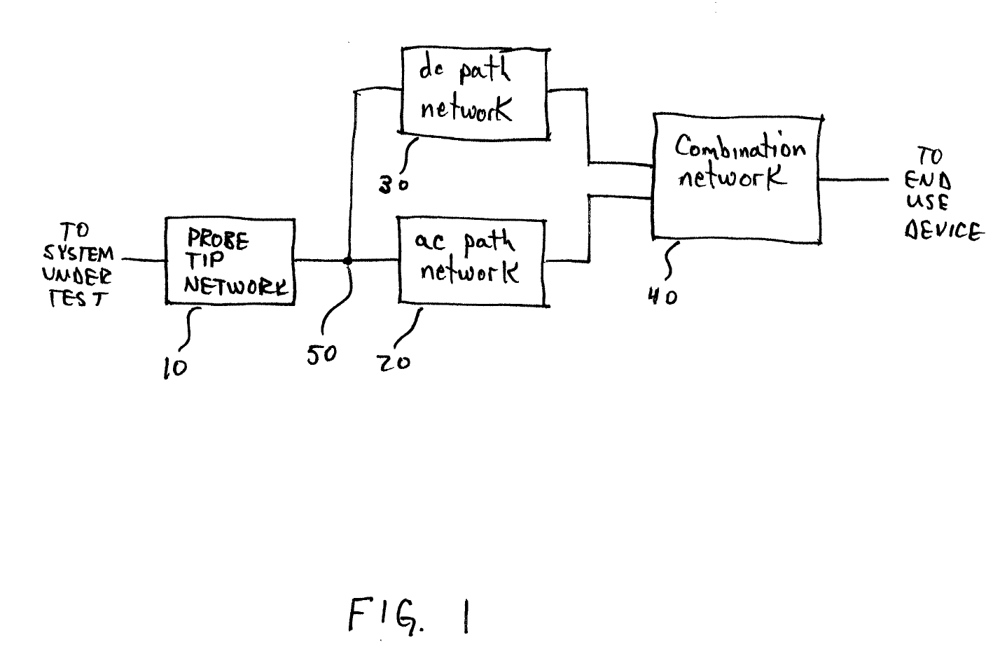

FIG. 1 is a general block diagram of a probe according to the invention. Block 10 is a probe tip network which detects a signal in a system under test. Block 20 is an ac path network. The ac path network blocks any dc signal detected by the probe tip network and processes any remaining ac signals. Block 30 is a dc path network. The dc path network process the dc signal detected by the probe tip network and optimizes the dc signal separately from the ac signal. Block 40 is a combination network which combines the ac signals and the dc signals and outputs the result to an end use device.

The probe tip network, block 10, is connected to a system under test at one end and to the ac path network and dc path network at the other end. Node 50 indicates conceptually the point at which the dc signal and the ac signal separate. At the other end, the ac path network is connected to block 40, the combination network. At the other end, the dc path network is connected also to block 40, the combination network. A connecting cable, not shown, transfers the signal, ac and dc signals, produced by the probe tip network to node 50. The ac path network, block 20, blocks any dc signals and transfers any ac signals onto the ac network. The dc path network, block 30, transfers any dc signals. DC signals which pass through the dc path network are optimized within the dc path network. By separating the dc component and the ac component from the detected signal, a larger DC offset voltage can be utilized without the worry of the ac component. The combination network, block 30, reproduces the detected signal for the end-use device. The dc signal can be optimized efficiently by the dc path network up to roughly 400 Hertz. At such a low frequency, utilizing larger dc offset voltages will not cause any undue destabilizing effect on the dc signal.

The probe tip network, block 10, may be constructed as represented in FIG. 2 with a parallel combination of a resistor Rᵢₙ 12 and a capacitor Cᵢₙ 14. The combination is placed in series between the probe tip 11 and connection leading to block 20, line 13. A common ground, line 100, runs through the probe tip network from the system under test to block 20.

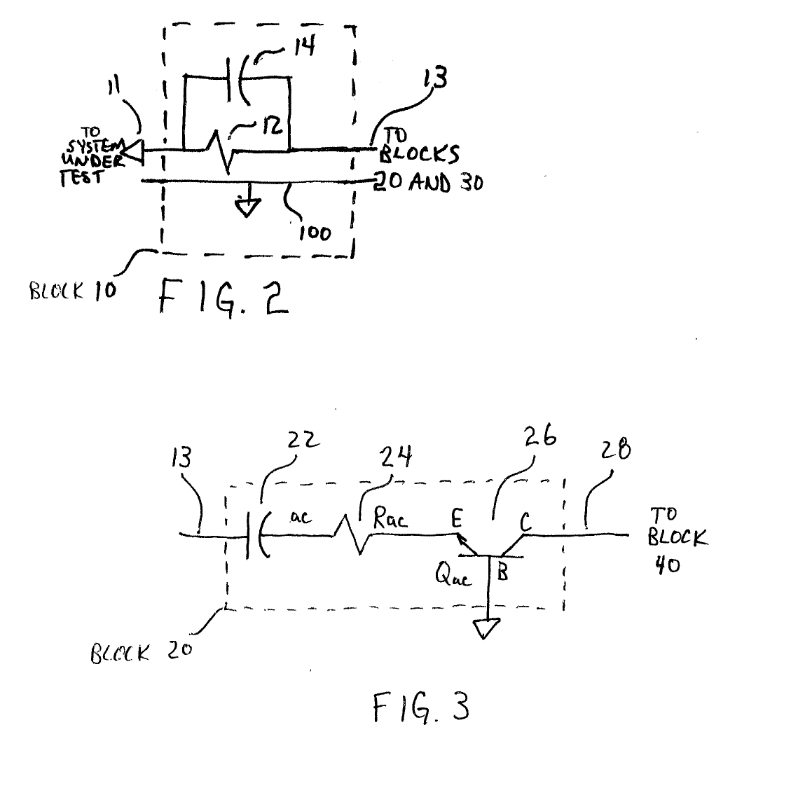

A preferred form of the ac path network is shown in FIG. 3. The signal from the probe tip network, block 10, enters the ac path network via line 13. The signal exiting the probe tip network will be comprised of two components, an ac component and a dc component. Capacitor C_{ac} 22 acts to block the dc component from entering the ac path network, block 20. Capacitor C_{ac} 22 is connected to line 13 at one end, and at the other end is connected to resistor 24. Resistor 24 R_{ac} is connected at the other end to the emitter of a common-base configured bipolar junction transistor, Q_{ac} 26. The base of Q_{ac} 26 is connected to the common ground and the collector is connected to block 30 via line 28. The transistor Q_{ac} functions in such a manner that the current into the emitter equals the current out of the collector.

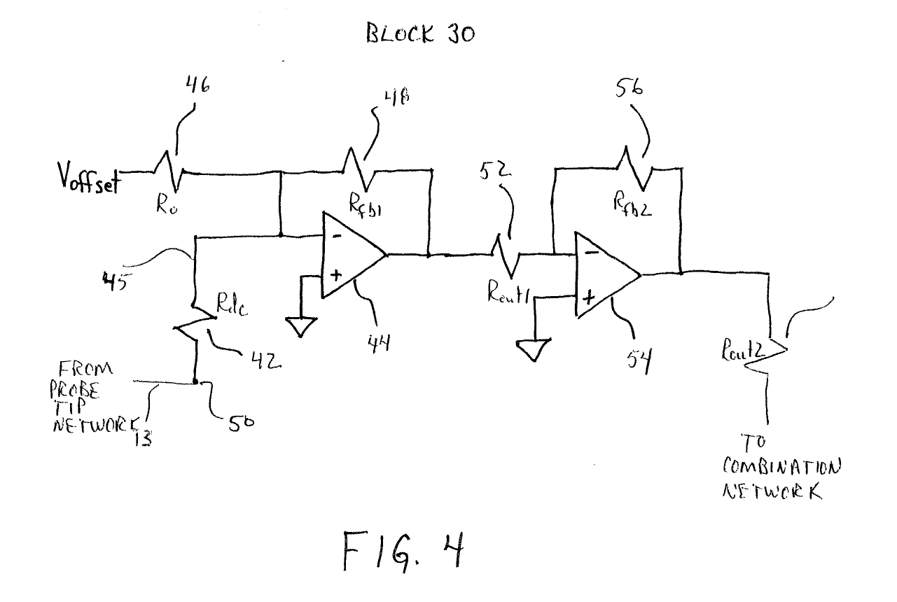

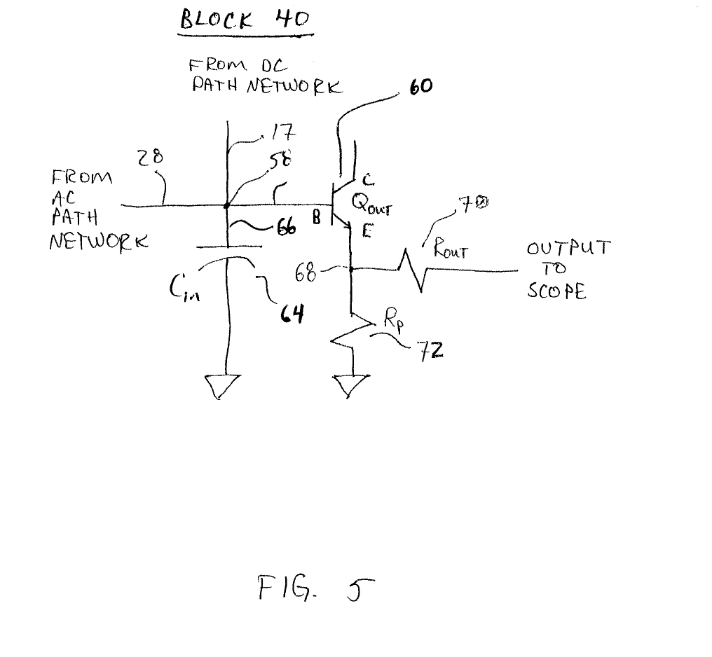

FIG. 4 is a schematic of a preferred form of the dc path network, block 30. The dc path network the dc signal sensed by the probe tip network. The dc path network connects to the probe tip network at node 50 (see FIG. 1) via line 13. On the other end of node 50 is Resistor R_{dc} 42. R_{dc} 42 connects to the negative terminal of a first operational amplifier 44 via line 45. The negative terminal of op amp 44 also connects to V_{offset} via line 45. Resistor Ro 46 is interposed between V_{offset} and op amp 44. Resistor R_{fb1} 48 is in the feedback loop of op amp 44. The feedback loop connects back into the negative terminal of op amp 44. The positive terminal of op amp 44 connects to ground. The output of op amp 44 connects to resistor Rₒᵤₜ₁ 52. Rₒᵤₜ₁ 52 connects to the negative terminal of a second operational amplifier 54. The positive terminal of op amp 54 connects to ground. The output of op amp 54 feeds back to the negative terminal through resistor R_{fb2} 56. The output of op amp 54 also connects to resistor Rₒᵤₜ₂. Rₒᵤₜ₂ connect to line 17 which connects to the combination network, block 40.

FIG. 5 shows a preferred embodiment of the combination network in accordance with the invention. Outputs from the DC path network (via line 17), block 30, and the ac path network (via line 28), block 20, combine at node 58. Node 58 connects to the base of transistor Qₒᵤₜ 60 via line 62 and capacitor Cᵢₙ 64 via line 66. The emitter of transistor Qout 60 connects to node 68. Node 68, in turn, connects to resistor Rₒᵤₜ 70 and resistor Rₚ 72. Rₒᵤₜ 70 connects to the output. Capacitor Cᵢₙ 64 connects to ground.

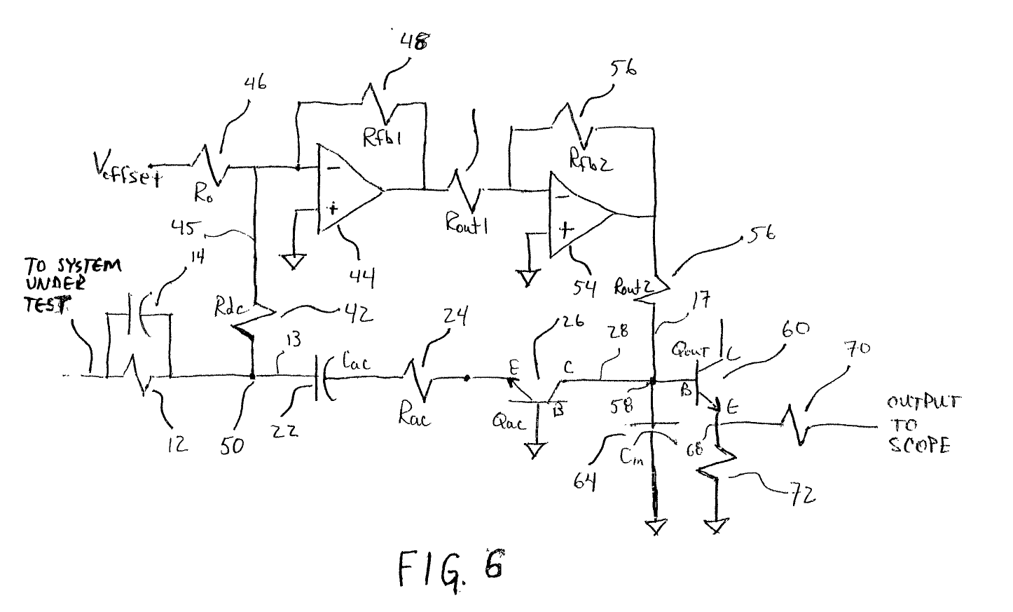

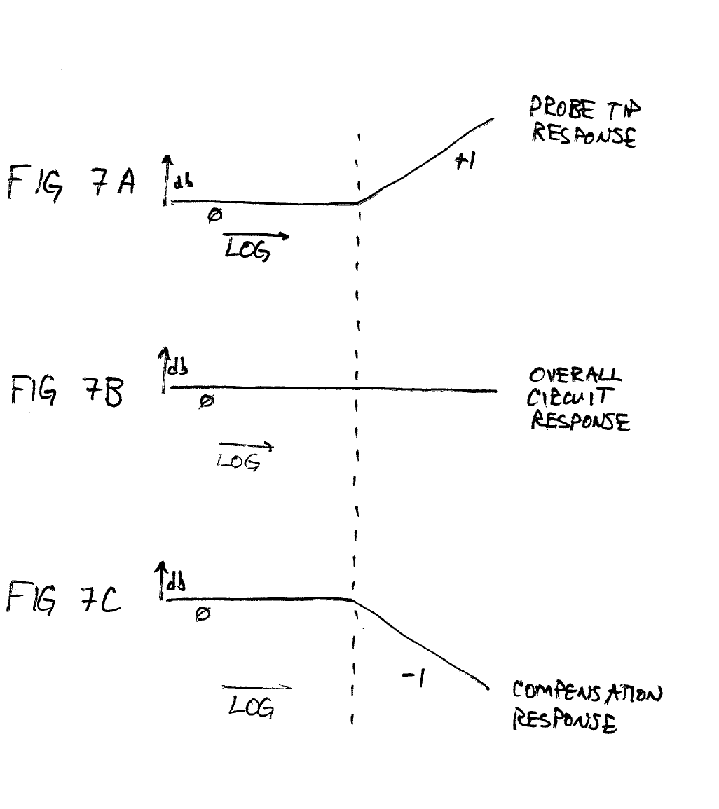

FIG. 6 is a diagram illustrating the combined circuitry of the previous figures of a probe according to the invention. The frequency response for the probe network is shown in FIGS. 7A, 7B and 7C. The input from the probe tip passes through the RC combination, elements 14 and 12, connecting to the system under test through a transmission line (such as a trace on a PC board). This parallel tip RC creates a zero and the combination of Rₒᵤₜ₂ 56 and Cᵢₙ 64 creates a pole. The zero created by the parallel tip RC can be seen in FIG. 7A. FIG. 7A shows the frequency response for the probe tip. The pole created by the combination of Rₒᵤₜ₂ 56 and Cᵢₙ 64 can be seen in FIG. 7C. FIG. 7C shows the frequency response for the combination network and the dc path network. FIG. 7B shows the frequency response for the overall probe tip network. It is understood by those skilled in the art that the zero and pole created by the probe tip network can be adjusted so that they occur at the same or different frequencies. The values of the resistors and capacitors responsible for the zero and pole determine the frequency location thereof. In a preferred embodiment of the invention, the zero and pole of the probe tip network are at 20 MHz. It is understood that the frequency response for portions of the circuit not shown in FIGS. 7A-C is flat, i.e. there are no poles or zeroes present.

Looking again at FIG. 6, the input from the probe tip, which may be a resistor and capacitor in parallel built using thick film technology, is passed through a coaxial cable and enters the circuit in FIG. 6 where it connects to the system under test. The signal passes through the RC circuit comprised of Cᵢₙ 14 and Rᵢₙ 12 where a frequency zero results. In a preferred embodiment of the invention, the values of Cᵢₙ and Rᵢₙ are chosen in such a manner that the RC circuit minimally loads the circuit under test. It is understood that a person skilled in the art will comprehend the need to minimally load the circuit and choose values for Rᵢₙ 12 and Cᵢₙ 14 adequate to that end. Not shown in FIG. 6 is the transmission cable. The transmission cable, Z₀, is present between the Probe Tip Network, Cᵢₙ and Rᵢₙ, and point 50.

At point 50, the signal divides. The DC portion of the signal will travel through the upper part, i.e. through R_{dc} 42. Preferrably, Rdc 42 is a 10 KΩ resistive component. It is understood by those skilled in the art that ideal separation of the dc and ac components will not normally occur. As such, in a preferred embodiment of the invention, the dc path of the circuit will carry the portion of the signal which has a frequency less than 400 Hz. The ac portion of the signal will travel through the lower portion of the circuit, i.e. through C_{ac}. As discussed, the dc portion of the signal is optimized separately from the ac portion. The two portions of the signal are combined at point 58. The combined signal is output to the measurement tools.

Determination of the values of the components of a probe in accordance with the invention is understood by those skilled in the art. The time constants of the two RC networks creating the zero and pole must be equal so that the zeros and poles balance out as shown in FIG. 7. Also in one embodiment of the invention, the length of the cable, Z₀, is 2 meters and has a characteristic impedance of 75 Ω. Those skilled in the art will understand that the length of the cable, Z₀, effects the noise of the circuit and limits the maximum achievable bandwidth of the probe.

Other possible variations in the specific embodiments disclosed are possible. It is understood that although particular embodiments of the invention have been described and illustrated herein, it is recognized that modifications and variations may readily occur to those skilled in the art and consequently, it is intended that the claims be interpreted to cover such modifications and equivalents.

What is claimed is:

1. A probe apparatus for detecting electronic signals in a system under test and replicating said signals for an end use device, comprising:
a detection means for detecting said first electronic signals and producing responses to said electronic signal, said detection means having a transmission zero in the frequency response at a preselected frequency and said responses are second electronic signal having a dc component and an ac component;
a transmission cable connected to said detection means;
a dc path network having a first and second end, said first end connecting to said transmission cable and said second end connected to a combination network, said combination network and said dc path network together having a transmission pole in the frequency response at the preselected frequency;
an ac path network having a first and second end, said first end connected to said transmission cable and said second end connected to the combination network;
wherein said dc component travels through said dc path network and said ac component travels through said ac path network, said dc component and said ac component combine in said combination network and said combination network connects to said end use device.

2. The probe apparatus of claim 1, wherein said ac components are roughly above 400 Hz and said dc components are roughly below 400 Hz.

3. The probe apparatus of claim 2, wherein said dc path network comprises a means for optimizing said dc component.

4. The probe apparatus of claim 3, wherein said means for optimizing said dc component comprises a plurality of amplification means coupled with a means for providing a voltage offset to one of said amplification means.

5. The probe apparatus of claim 4, wherein said ac network path comprises a means of blocking the dc component.

6. The probe apparatus of claim 5, wherein said ac network path further comprises a resistive element and a transistor element in series with said blocking means.

7. The probe apparatus of claim 6, wherein said combination network comprises a transistor having an emitter, a base and a collector, wherein said base is connected to the dc network path, and to the ac network path and said emitter is connected of a voltage divider comprised of a pair of resistors, one of said pair of resistors connecting to an output to said end use device.

8. The probe apparatus of claim 7, wherein said plurality of amplification means is a pair of operational amplifiers.

9. The probe apparatus of claim 8, wherein each of said pair of operational amplifiers has a resistor in the feed back loop, a first amplifier resistor connects to the negative terminal of one of said operational amplifiers and to the probe tip network, a second amplifier resistor connects to the negative terminal of one of said operational amplifiers and to the output of one of said operational amplifiers and a third amplifier resistor connects to the negative terminal of one of said operational amplifiers and to the means for providing a voltage offset.

10. The probe apparatus of claim 9, wherein said probe tip network is a parallel RC network.

11. The probe apparatus of claim 2, wherein said probe tip network is a parallel RC network.

12. robe apparatus for detecting first electronic signal in a system under test and replicating said first signals for an end use device, comprising:
detection means for detecting said first electronic signals and producing responses to said electronic signal, said detection means having a transmission zero in the frequency response at a preselected frequency and said responses are second electronic signal having a dc component and an ac component;
a means of separating the dc components from the ac components;
a means of transmitting said responses from said detection means to said mean of separating;
a means of conditioning said dc components resulting in conditioned dc components;
a means of conditioning said ac components resulting in conditioned ac components;
a means of combining said conditioned dc components with said ac components resulting in conditioned responses; and
a means of outputting said conditioned responses to said end use device.

13. The probe apparatus of claim 12, wherein said detection means is a parallel RC circuit.

14. The probe apparatus of claim 13 wherein said means of separating the dc components from the ac components is a blocking capacitor, said blocking capacitor allowing ac components to travel through an ac network path and forcing said dc components to travel through a dc network path.

15. The probe apparatus of claim 14, wherein said ac components are above 600 Hz and said dc components are below 600 Hz.

16. The probe apparatus of claim 15, wherein said ac components are above 200 Hz and said dc components are below 200 Hz.
